(19) United States
(12) Patent Application Publication
(10) Pub. No.: US 2024/0387598 A1
(43) Pub. Date: Nov. 21, 2024

(54) PHOTOELECTRIC CONVERSION DEVICE, SYSTEM USING PHOTOELECTRIC CONVERSION DEVICE, AND MOVING BODY

(71) Applicant: CANON KABUSHIKI KAISHA, Tokyo (JP)

(72) Inventors: AYMANTAREK ABDELGHAFAR, Tokyo (JP); KAZUHIRO MORIMOTO, Kanagawa (JP); HIROSHI SEKINE, Kanagawa (JP)

(21) Appl. No.: 18/666,565

(22) Filed: May 16, 2024

(30) Foreign Application Priority Data
May 19, 2023 (JP) 2023-083367

(51) Int. Cl. H01L 27/146

(52) U.S. Cl. CPC H01L 27/14643; H01L 27/14625; H01L 27/14636

(57) ABSTRACT

A conversion device includes a substrate made of a first material, which includes a photodiode, a conversion layer made of a second material whose band gap is smaller than a band gap of the first material, and a region made of a third material at least including an element of the first material or the second material and being in contact with the substrate and the conversion layer, wherein an area of the region is smaller than an area of the conversion layer in a top plan view.

### BACKGROUND

### Technical Field

The aspect of the embodiments relates to a photoelectric conversion device, a system, and a moving body.

### Description of the Related Art

Japanese Unexamined Patent Application Publication No. 2022-500882 discusses a method for improving near infrared sensitivity by photoelectrically converting photons in a germanium (Ge) absorption layer arranged immediately above an avalanche photodiode made of silicon (Si).

There is a possibility that noise is increased because of a lattice mismatch arising at a junction interface between the materials with different lattice constants.

### SUMMARY

According to an aspect of the embodiments, a conversion device includes a substrate made of a first material, which includes a photodiode, a conversion layer made of a second material whose band gap is smaller than a band gap of the first material, and a region made of a third material at least including an element of the first material or the second material and being in contact with the substrate and the conversion layer, wherein an area of the region is smaller than an area of the conversion layer in a top plan view.

Further features of the disclosure will become apparent from the following description of exemplary embodiments with reference to the attached drawings.

### BRIEF DESCRIPTION OF THE DRAWINGS

FIG. 1 is a schematic diagram of a photoelectric conversion device according to a present exemplary embodiment.

FIG. 2 is a schematic diagram of a photodiode (PD) substrate of the photoelectric conversion device according to the present exemplary embodiment.

FIG. 3 is a schematic diagram of a circuit substrate of the photoelectric conversion device according to the present exemplary embodiment.

FIG. 4 is a diagram illustrating a configuration example of a pixel circuit of the photoelectric conversion device according to the present exemplary embodiment.

FIGS. 5A to 5C are schematic diagrams illustrating driving of the pixel circuit of the photoelectric conversion device according to the present exemplary embodiment.

FIG. 6 is a diagram illustrating a plan view of a pixel according to a first exemplary embodiment.

FIG. 7 is a diagram illustrating a cross-sectional view of the pixel according to the first exemplary embodiment.

FIG. 8 is a diagram illustrating a cross-sectional view of a pixel according to a second exemplary embodiment.

FIG. 9 is a diagram illustrating a cross-sectional view of a pixel according to a third exemplary embodiment.

FIG. 10 is a diagram illustrating a cross-sectional view of a pixel according to a fourth exemplary embodiment.

FIG. 11 is a diagram illustrating a cross-sectional view of a pixel according to a fifth exemplary embodiment.

FIG. 12 is a diagram illustrating a cross-sectional view of a pixel according to a sixth exemplary embodiment.

FIG. 13 is a diagram illustrating a plan view of a pixel according to a seventh exemplary embodiment.

FIG. 14 is a diagram illustrating a cross-sectional view of the pixel according to the seventh exemplary embodiment.

FIG. 15 is a diagram illustrating a cross-sectional view of a pixel according to an eighth exemplary embodiment.

FIG. 16 is a functional block diagram of a photoelectric conversion system according to a ninth exemplary embodiment.

FIGS. 17A and 17B are functional block diagrams of a photoelectric conversion system according to a tenth exemplary embodiment.

FIG. 18 is a functional block diagram of a photoelectric conversion system according to an eleventh exemplary embodiment.

FIG. 19 is a functional block diagram of a photoelectric conversion system according to a twelfth exemplary embodiment.

FIGS. 20A and 20B are functional block diagrams of a photoelectric conversion system according to a thirteenth exemplary embodiment.

### DESCRIPTION OF THE EMBODIMENTS

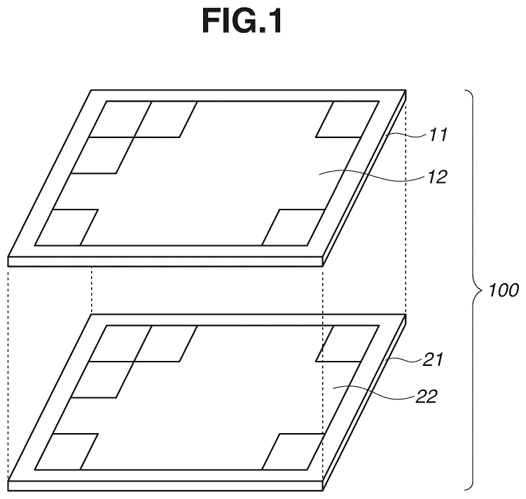

FIG. 1 is a diagram illustrating a configuration of a laminated-type photoelectric conversion device 100 according to a present exemplary embodiment of the present disclosure. The photoelectric conversion device 100 includes two chips, i.e., a sensor chip 11 and a circuit chip 21, which are laminated and electrically connected to each other.

A pixel region 12 is arranged on the sensor chip 11, and a circuit region 22 for processing a signal detected from the pixel region 12 is arranged on the circuit chip 21.

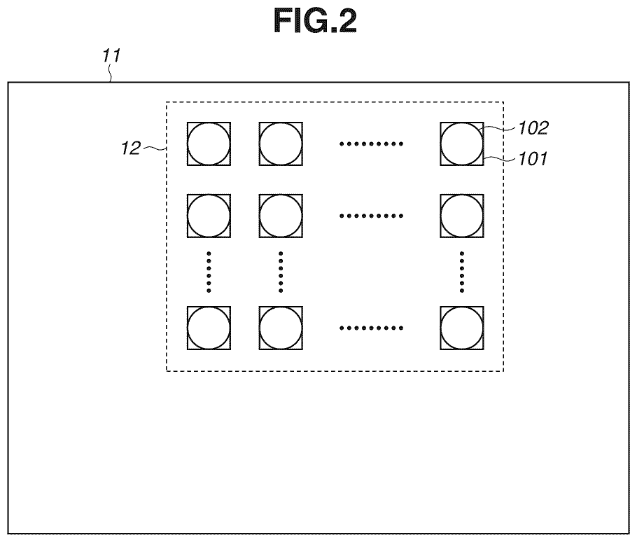

FIG. 2 is a diagram illustrating layout of the sensor chip 11. Pixels 101, each of which has a photoelectric conversion portion 102 including an avalanche photodiode (hereinafter, called “APD”), are arrayed two-dimensionally to form the pixel region 12. Although the pixels 101 typically functions to form images, the pixels 101 do not always have to form images in a case where the pixels 101 are used for the purpose of Time-of-Flight (TOF). In other words, the pixels 101 may function to measure an arrival time and an amount of light.

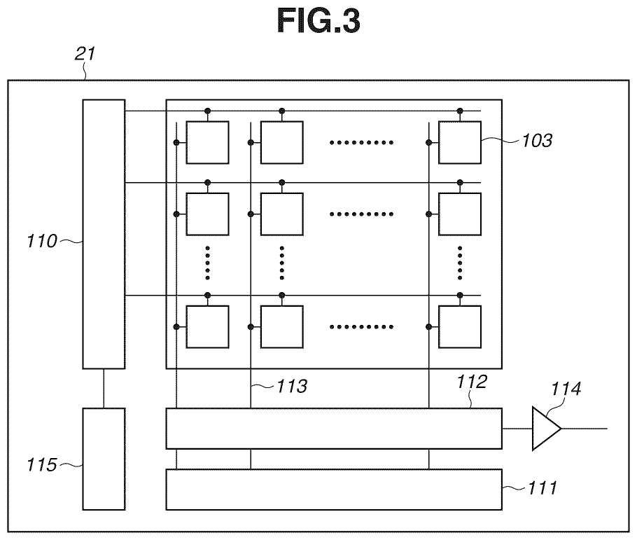

FIG. 3 is a diagram illustrating a configuration of the circuit chip 21. The circuit chip 21 includes signal processing units 103 for processing electric charges photoelectrically converted by the photoelectric conversion portions 102 illustrated in FIG. 2, a read-out circuit 112, a control pulse generation unit 115, a horizontal scanning circuit unit 111, a signal line 113, and a vertical scanning circuit unit 110.

Each of the photoelectric conversion portions 102 in FIG. 2 and each of the signal processing units 103 in FIG. 3 are electrically connected to each other via connection wiring arranged for each of the pixels 101.

The vertical scanning circuit unit 110 receives a control pulse supplied from the control pulse generation unit 115 and supplies the control pulse to each of the pixels 101. A logic circuit such as a shift register or an address decoder is used as the vertical scanning circuit unit 110.

Signals output from the photoelectric conversion portions 102 of the pixels 101 are processed by the signal processing units 103. A counter and a memory are arranged on each of the signal processing units 103, and a digital value is stored in the memory. In order to read out signals from the memories of the pixels 101 where digital signals are retained, the horizontal scanning circuit unit 111 inputs a control pulse for sequentially selecting each of columns to the signal processing units 103. The signals are output to the signal line 113 from the signal processing units 103 of the pixels 101 of a column selected by the vertical scanning circuit unit 110.

The signals output to the signal line 113 are output to a recording unit or a signal processing unit arranged on the outside of the photoelectric conversion device 100 via an output circuit 114.

In FIG. 2, arrays of pixels 101 in the pixel region 12 may be arranged one-dimensionally. A function of the signal processing unit 103 does not always have to be individually provided to each of the pixels 101. For example, one signal processing unit 103 may be shared by a plurality of pixels 101, so that signal processing may be executed sequentially.

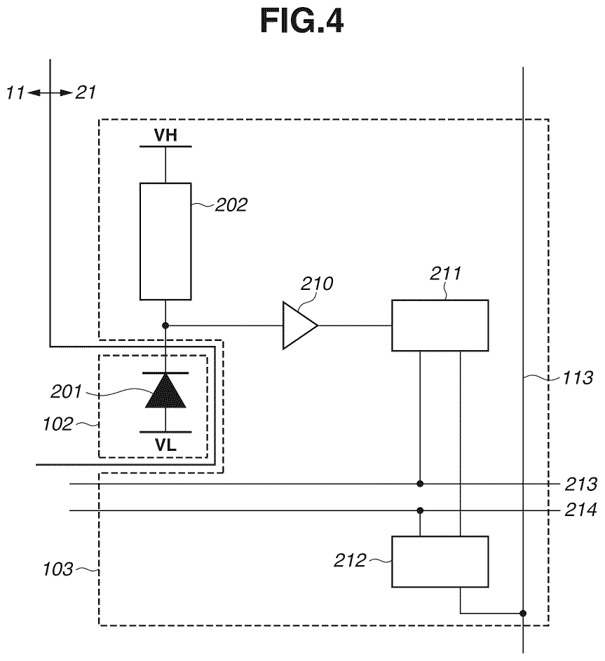

FIG. 4 is an example of a block diagram including the equivalent circuit of the circuits illustrated in FIGS. 2 and 3. In FIG. 2, photoelectric conversion portions 102 including APDs 201 are arranged on the sensor chip 11, and the other members are arranged on the circuit chip 21. The APD 201 executes photoelectric conversion to generate a pair of electric charges depending on incident light. A voltage VL (first voltage) is supplied to the anode of the APD 201. Further, a voltage VH (second voltage) higher than the voltage VL supplied to the anode is supplied to the cathode of the APD 201. A reverse bias voltage which causes the APD 201 to perform avalanche multiplication is supplied to each of the anode and the cathode thereof. By supplying the above-described voltage thereto, avalanche multiplication occurs in the electric charges generated from the incident light, so that avalanche current is generated.

In a case where the reverse bias voltage is supplied to an anode and a cathode of an APD, the APD is operated in a Geiger mode and a linear mode. In the Geiger mode, a difference between the electric potentials of the anode and the cathode is greater than a breakdown voltage. In the linear mode, a difference between the electric potentials of the anode and the cathode is close to, or less than or equal to the breakdown voltage. An APD operated in the Geiger mode is called a single-photon avalanche diode (SPAD). For example, −30V and 1V are respectively supplied as the voltage VL (first voltage) and the voltage VH (second voltage).

A quench element 202 is connected to a power source for supplying the voltage VH and the APD 201. The quench element 202 has a function for converting a change of avalanche currents generated in the APD 201 into a voltage signal. When signal multiplication caused by avalanche multiplication occurs, the quench element 202 functions as a load circuit (quench circuit) to suppress the avalanche multiplication by suppressing the voltage supplied to the APD 201 (i.e., quench operation).

The signal processing unit 103 includes a waveform shaping unit 210, a counter circuit 211, and a selection circuit 212. In this specification, the signal processing unit 103 may include any one of the waveform shaping unit 210, the counter circuit 211, and the selection circuit 212.

The waveform shaping unit 210 shapes a potential change of the cathode of the APD 201 acquired at the time of photon detection into a pulse signal, and outputs the pulse signal. For example, an inverter circuit is used as the waveform shaping unit 210. In the example illustrated in FIG. 4, one inverter is used as the waveform shaping unit 210. However, a circuit which includes a plurality of inverters connected in series, or another circuit having a waveform shaping effect can also be used.

The counter circuit 211 counts pulse signals output from the waveform shaping unit 210 and retains a count value. When a control pulse pRES is supplied thereto via a drive line 213, the signals retained by the counter circuit 211 is reset.

A control pulse pSEL is supplied to the selection circuit 212 from the vertical scanning circuit unit 110 in FIG. 2 via a drive line 214 in FIG. 4 (not illustrated in FIG. 3), so that the electrical connection between the counter circuit 211 and the signal line 113 is switched on and off. For example, the selection circuit 212 includes a buffer circuit for outputting a signal.

The electrical connection can be switched by arranging of a switch such as a transistor at a position between the quench element 202 and the APD 201 or at a position between the photoelectric conversion portion 102 and the signal processing unit 103. Similarly, the voltage VH or VL supplied to the photoelectric conversion portion 102 can also be electrically switched by using a switch such as a transistor.

In the present exemplary embodiment, a configuration using the counter circuit 211 is described. However, the photoelectric conversion device 100 may acquire a pulse detection timing by using a time-to-digital converter (TDC) and a memory instead of using the counter circuit 211. At this time, a generation timing of the pulse signal output from the waveform shaping unit 210 is converted into a digital signal through the TDC. In order to measure a timing of the pulse signal, a control pulse pREF (reference signal) is supplied to the TDC from the vertical scanning circuit unit 110 in FIG. 1 via a drive line. The TDC uses the control pulse pREF as a reference to acquire a signal when an input timing of a signal output from the pixel 101 via the waveform shaping unit 210 is taken as a relative time, as a digital signal.

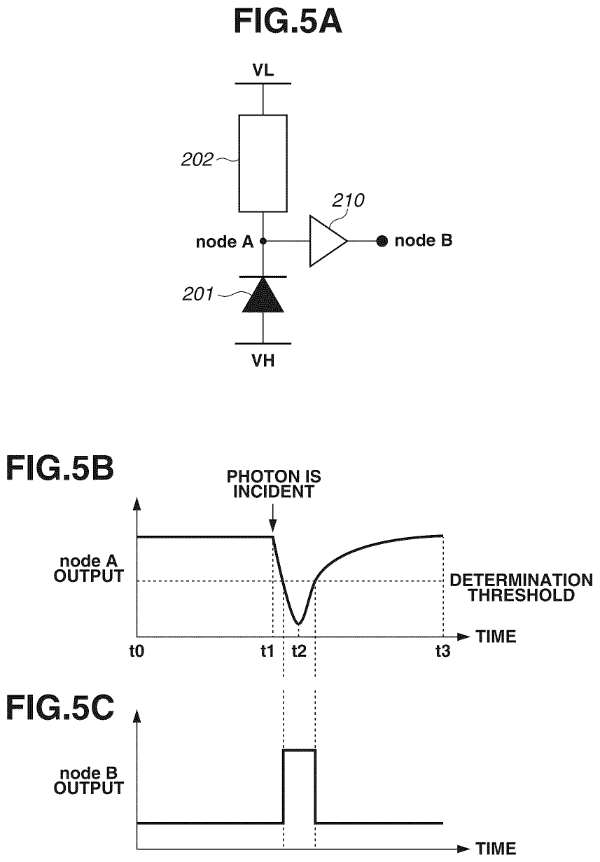

FIGS. 5A to 5C are diagrams schematically illustrating a relationship between the operation of the APD 201 and the output signal. FIG. 5A is a diagram illustrating a portion including the APD 201, the quench element 202, and the waveform shaping unit 210 extracted from FIG. 4. Here, an input side and an output side of the waveform shaping unit 210 are respectively called “node A” and “node B”. A change of the waveform of the node A in FIG. 5A is illustrated in FIG. 5B, and a change of the waveform of the node B in FIG. 5A is illustrated in FIG. 5C.

In a period between time t0 to time t1, a potential difference of the voltage VH and the voltage VL is applied to the APD 201 in FIG. 5A.

When photons are incident on the APD 201 at time t1, avalanche multiplication current flows in the quench element 202, and a voltage of the node A is dropped. When the amount of voltage drop becomes greater, and a difference in electric potentials applied to the APD 201 becomes smaller, the avalanche multiplication occurring in the APD 201 is stopped, so that a voltage level of the node A will not be lower than a certain level. After that, electric current for compensating the voltage drop amount flows into the node A from the voltage VH, so that electric potential of the node A is settled in the original potential level at time t3.

At this time, a portion of the output waveform which exceeds a certain threshold at the node A is shaped by the waveform shaping unit 210 and output from the node B as a signal.

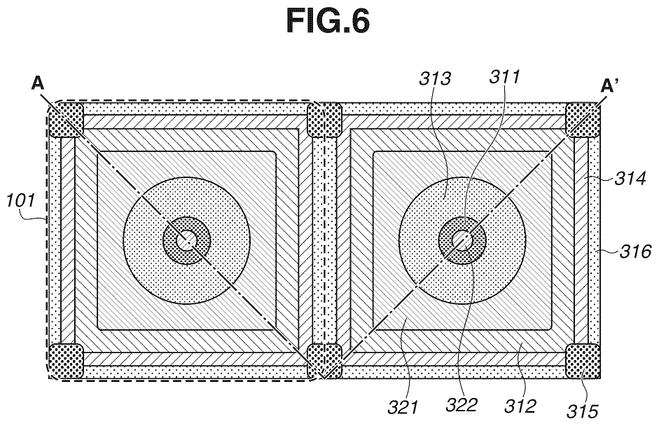

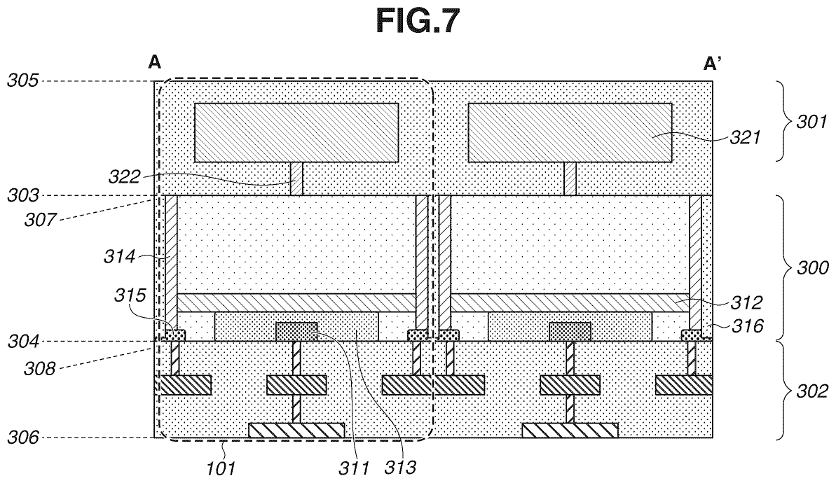

A photoelectric conversion device according to a first exemplary embodiment is described with reference to FIGS. 6 to 7.

FIG. 6 is a diagram illustrating a plan view of two pixels of the photoelectric conversion device according to the present exemplary embodiment. FIG. 7 is a diagram illustrating a cross-sectional view of the two pixels of the photoelectric conversion device taken along a line A-A′ in FIG. 6. Reference numbers applied to semiconductor regions and structures in FIG. 7 conform to reference numbers in FIG. 6. For the sake of clear explanation and illustration of a positional relationship between respective elements, the plan view in FIG. 6 also includes the elements illustrated in perspective.

A region surrounded by a dotted line in each of FIGS. 6 and 7 is a pixel 101. As illustrated in FIG. 6, a pixel 101 is electrically isolated from an adjacent pixel 101 by an isolation trench 316. A fifth semiconductor region 315 is arranged at each of diagonal positions of the pixel 101, and a fourth semiconductor region 314 is arranged on the inner side of the isolation trench 316. A first semiconductor region 311, a second semiconductor region 312, and a third semiconductor region 313 are concentrically arranged on a semiconductor substrate 300. In a region close to the light-incident face of the semiconductor substrate 300, a columnar-shaped columnar structure 322 is arranged to be concentric with the first semiconductor region 311.

As illustrated in FIG. 7, the pixel 101 has a structure in which a semiconductor substrate 300, a photoelectric conversion layer 301, and a wiring layer 302 are laminated with each other in a cross-sectional view. The semiconductor substrate 300 is made of a first material, and includes a first face 303 and a second face 304. The semiconductor substrate 300 is laminated with the photoelectric conversion layer 301, so that the first face 303 thereof faces a seventh face 307 of the photoelectric conversion layer 301. The photoelectric conversion layer 301 has a third face 305 on the side opposite to the seventh face 307 side. Further, the semiconductor substrate 300 is laminated with the wiring layer 302, so that the second face 304 thereof faces an eighth face 308 of the wiring layer 302. The wiring layer 302 has a fourth face 306 on the side opposite to the eighth face 308 side. In the present exemplary embodiment, the third face 305 is a light-incident face.

The semiconductor substrate 300 is made of the first material, and the first semiconductor region 311 of the first conductive type is arranged on the second face 304 of the semiconductor substrate 300. Further, the second semiconductor region 312 of the second conductive type is arranged in a region closer to the first face 303 than the first semiconductor region 311. The third semiconductor region 313 of the first conductive type is arranged to surround the first semiconductor region 311, and the semiconductor substrate 300 further includes the fourth semiconductor region 314 of the second conductive type and the fifth semiconductor region 315 of the second conductive type. The isolation trench 316 is arranged in a region between the pixels 101.

A voltage VH (first voltage) is applied to the first semiconductor region 311 of the first conductive type. On the other hand, a voltage VL (second voltage) is supplied to the fifth semiconductor region 315 of the second conductive type, and the voltage VL is also applied to the second semiconductor region 312 of the second conductive type via the fourth semiconductor region 314 of the second conductive type. An avalanche multiplication region is formed in a region where the first semiconductor region 311 of the first conductive type and the second semiconductor region 312 of the second conductive type come close to each other.

By supplying the above voltages VH and VL, when electric charges generated from incident light pass through the avalanche multiplication region, the avalanche multiplication occurs in the electric charges to cause avalanche current to be generated. The fourth semiconductor region 314 of the second conductive type serves as an isolation region between the adjacent pixels 101.

In order to reduce the contact resistance between the semiconductor substrate 300 and the wiring layer 302, the fifth semiconductor region 315 of the second conductive type is arranged on the second face 304 of the semiconductor substrate 300, at each of diagonal positions of the pixel 101. At this time, the impurity concentration of the second conductive type of the fifth semiconductor region 315 is higher than the impurity concentration of the second conductive type of the fourth semiconductor region 314. A side wall portion of the isolation trench 316 is covered by the fourth semiconductor region 314. The occurrence of crosstalk, caused by leakage of light incident on one pixel 101 into the adjacent pixel 101, can be prevented by the isolation trench 316. Further, the third semiconductor region 313 of the first conductive type is arranged to cover the corners of the first semiconductor region 311 of the first conductive type, thereby formation of a local high electric field is suppressed in a region between the first semiconductor region 311 of the first conductive type and the fifth semiconductor region 315 of the second conductive type.

The photoelectric conversion layer 301 is made of the second material, and includes a photoelectric conversion region 321. A band gap of the second material is smaller than that of the first material, so that quantum efficiency thereof at a near-infrared waveband is higher than that of the first material. Generally, a semiconductor can photoelectrically convert light having energy greater than band gap energy. Because the band gap of the second material is smaller than the band gap of the first material, energy for photoelectric conversion is also small. In other words, light of a wave length longer than that of light photoelectrically convertible by the first material can be photoelectrically converted by the second material. For example, the first material is silicon (Si), whereas the second material is germanium (Ge). Germanium can also be used as an intrinsic semiconductor, or can be used as an impurity semiconductor to which impurities such as phosphorus (P), arsenic (As), antimony (Sb), boron (B), aluminum (Al), and gallium (Ga) are added. Further, the second material is not limited to germanium, and can be indium gallium arsenide (InGaAs) or germanium tin (GeSn). In the present exemplary embodiment, a diode formed as a result of the P-N junction of the first semiconductor region 311 and the second semiconductor region 312 and the photoelectric conversion region 321 are described as one APD.

A prescribed voltage is applied to the photoelectric conversion region 321. A voltage applied to the photoelectric conversion region 321 is described below in detail.

The columnar structure 322 made of the third material is arranged in a region between the semiconductor substrate 300 and the photoelectric conversion region 321 of the photoelectric conversion layer 301.

The first material constituting the semiconductor substrate 300 and the second material constituting the photoelectric conversion region 321 are different in the inter-lattice distance of atoms. Therefore, misfit dislocation caused by the lattice mismatch may occur in a junction interface when the semiconductor substrate 300 and the photoelectric conversion region 321 are joined together.

There is a risk that this misfit dislocation induces leak currents to cause noise to be increased.

In the present exemplary embodiment, the columnar structure 322 made of the third material, whose area is smaller than an area of the photoelectric conversion region 321, is arranged in a region between the semiconductor substrate 300 of the first material and the photoelectric conversion region 321 of the second material. With this configuration, in comparison to the case where the semiconductor substrate 300 and the photoelectric conversion region 321 are directly joined together, a junction area of members made of different materials is reduced, so that it is possible to suppress the influence of lattice mismatch arising in the junction area.

In the cross-sectional view, one columnar structure 322 is arranged for one pixel 101, and a width of the columnar structure 322 is narrower than a width of the photoelectric conversion region 321. The third material includes at least the first material or the second material. In one embodiment, the junction area is to be made as small as possible, although the effect of suppressing the influence of lattice mismatch can be acquired by the columnar structure 322 regardless of whether the columnar structure 322 is made of the first material or the second material. Specifically, in one embodiment, the columnar structure 322 is to be made of the second material because a dislocation defect arising in the junction interface with the semiconductor substrate 300 of the first material can be terminated in a region within the columnar structure 322. On the other hand, even in a case where the columnar structure 322 is made of only the first material, it is possible to acquire the effect of suppressing generation of noise by making an area of the junction interface be smaller than an area of the photoelectric conversion region 321.

The columnar structure 322 does not have to be arranged to overlap with the avalanche multiplication region in a top plan view. Further, a hetero junction portion (not illustrated in FIG. 7) for drawing out hole electric charges is arranged in a region between the photoelectric conversion region 321 and the fourth semiconductor region 314 of the second conductive type, in addition to the columnar structure 322. The anode voltage VL is supplied to the photoelectric conversion region 321 via the fourth semiconductor region 314 of the second conductive type, so that the electric charges are induced. In order to reduce the junction area, the hetero junction portion may have a columnar structure, or may have wiring in a region on one side of the photoelectric conversion region 321 close to the third face 305.

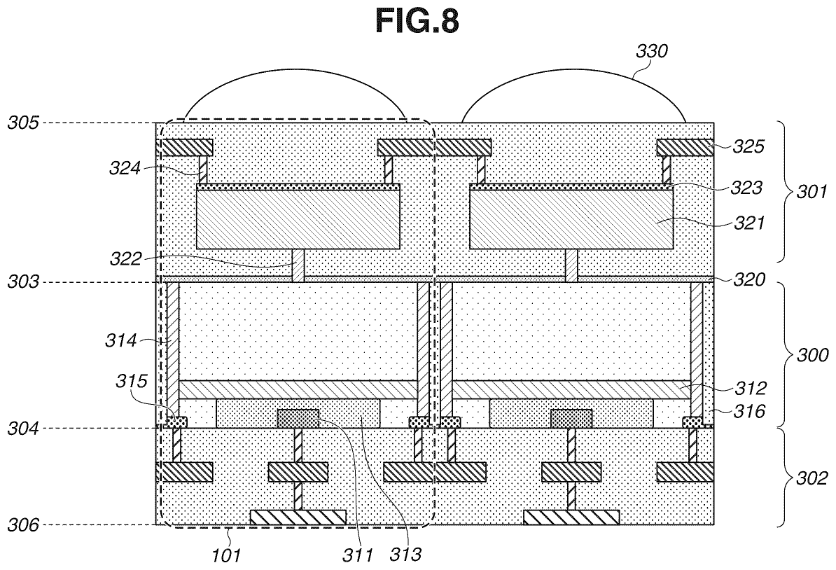

A photoelectric conversion device according to a second exemplary embodiment is described with reference to FIG. 8. Descriptions common to the first exemplary embodiment are omitted, and portions different from the first exemplary embodiment are mainly described.

FIG. 8 is a diagram illustrating a cross-sectional view of pixels 101 of the photoelectric conversion device according to the present exemplary embodiment. As illustrated in FIG. 8, a sixth semiconductor region 323 of the second material is arranged on one face of the photoelectric conversion region 321 which faces the third face 305, and an anode voltage is supplied to the sixth semiconductor region 323 via an anode contact 324 and a metallic wiring 325. Each of the pixels 101 has a microlens 330. Similar to the configuration illustrated in FIG. 6, in a top plan view, the photoelectric conversion region 321 is arranged on the semiconductor substrate 300 in a square shape, and anode contacts 324 are arranged at four corners thereof. Further, the columnar structure 322 of the third material includes at least the second material.

The configuration described in the present exemplary embodiment is different from the configuration described in the first exemplary embodiment in that the metallic wiring 325 is arranged in a region closer to the third face 305 than the photoelectric conversion region 321 is, and a voltage VL2 (third voltage) is applied to the photoelectric conversion region 321 via the anode contacts 324. The electric charges generated by photoelectric conversion in the photoelectric conversion region 321 pass through the columnar structure 322 of the third material to move to the semiconductor substrate 300. The metallic wiring 325 is mesh-like wiring which covers a region between the pixels 101, close to the third face 305. The metallic wiring 325 prevents light from being incident on a region other than the photoelectric conversion region 321, so that occurrence of optical crosstalk between the pixels 101 can be prevented thereby. Although it is assumed that the metallic wiring 325 in FIG. 8 extends to surround each of the pixels 101, the metallic wiring 325 may be arranged to surround a plurality of pixels 101 (e.g., four pixels 101).

Here, the voltage VL2 supplied to the photoelectric conversion region 321 via the metallic wiring 325 may be equivalent to or lower than the anode voltage VL applied to the fifth semiconductor region 315 and the second semiconductor region 312. In order to transfer the electric charges generated in the photoelectric conversion region 321, in one embodiment, a potential gradient inclining from the photoelectric conversion region 321 of the second material to the first semiconductor region 311 is formed.

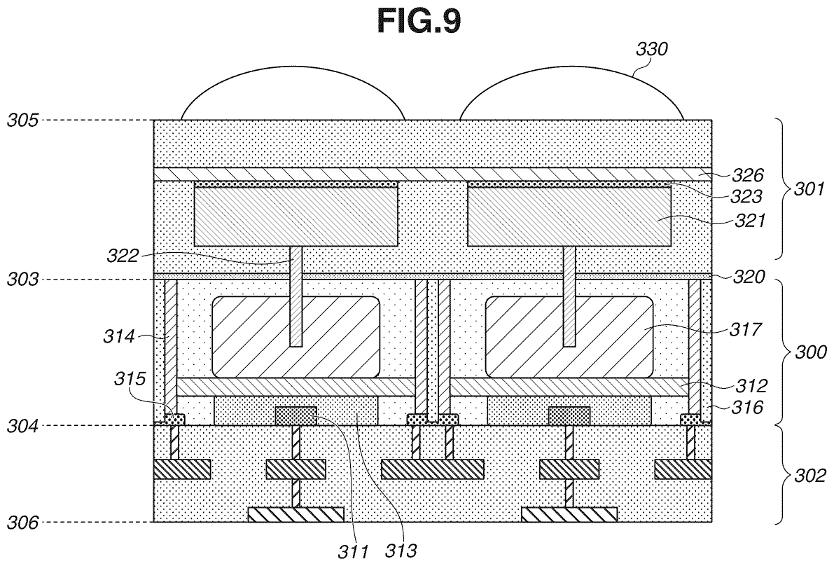

Further, the photoelectric conversion device illustrated in FIG. 8 is different from that of the first exemplary embodiment in that the photoelectric conversion device includes the pinning film 320 and the microlens 330. Noise generated at the junction interface can be suppressed by the pinning film 320 arranged on the first face 303. Further, it is possible to improve the sensitivity by collecting light to the photoelectric conversion region 321 by arranging the microlens 330 on the third face 305. In FIG. 9, the microlens 330 is arranged at the center of each of the pixels 101. However, the arrangement of the microlens 330 is not limited thereto. Depending on a relative position of the pixels 101 of the pixel array, the microlens 330 may be arranged to make the center thereof be shifted from the center of the pixel 101.

A photoelectric conversion device according to a third exemplary embodiment is described with reference to FIG. 9. Descriptions common to the photoelectric conversion devices according to the first and the second exemplary embodiments are omitted, and portions different from the second exemplary embodiment are mainly described.

FIG. 9 is a diagram illustrating a cross-sectional view of pixels 101 of the photoelectric conversion device according to the present exemplary embodiment. FIG. 9 is different from FIG. 8 in that a transparent electrode 326 is arranged in a region closer to the third face 305 than the photoelectric conversion region 321 is, and that the semiconductor substrate 300 includes an electric charge collection region 317. Further, FIG. 9 is different from FIG. 8 in that the columnar structure 322 of the third material extends to the inner portion of the semiconductor substrate 300 from the first face 303.

In the configuration illustrated in FIG. 8, there is a possibility that part of light heading toward the semiconductor substrate 300 is blocked by the metallic wiring 325 because the metallic wiring 325 is arranged in a region close to the light incident face of the semiconductor substrate 300. In the configuration according to the present exemplary embodiment, instead of the metallic wiring 325, the transparent electrode 326 is arranged in a region closer to the third face 305 than the photoelectric conversion region 321 is, and the voltage VL2 is applied to the photoelectric conversion region 321 via the transparent electrode 326. By using the transparent electrode 326, light obliquely incident on the semiconductor substrate 300 can also be photoelectrically converted, in addition to the components vertically incident on the photoelectric conversion region 321 from immediately above the photoelectric conversion region 321. In other words, an effect of improving the sensitivity to light can be acquired. In order to prevent degradation of sensitivity to near infrared light, in one embodiment, the transparent electrode 326 is to be made of a material which absorb near infrared light as little as possible.

Unlike the metallic wiring 325, the transparent electrode 326 can transmit light. Therefore, the transparent electrode 326 may be arranged to overlap with the entire face of the photoelectric conversion region 321 in addition to the outer edge portion of the pixel 101. A junction area between the transparent electrode 326 and the photoelectric conversion region 321 is increased, and thereby, the contact resistance can be reduced, and sufficient voltage can be applied to the electric charges photoelectrically converted at the photoelectric conversion region 321. Therefore, improvement can be expected with respect to the response speed at which the photoelectric conversion device responds to light.

Further, according to the photoelectric conversion device of the present exemplary embodiment, the semiconductor substrate 300 includes the electric charge collection region 317. The electric charge collection region 317 is a semiconductor region whose impurity concentration of the first conductive type is lower than that of the first semiconductor region 311. By arranging the electric charge collection region 317 in a region between the light incident face of the semiconductor substrate 300 and the second semiconductor region 312, it is possible to form a potential gradient inclining from the light incident face of the semiconductor substrate 300 to the avalanche multiplication region, so that it is possible to acquire an effect of facilitating the transfer of electric charges.

Further, according to the photoelectric conversion device of the present exemplary embodiment, the columnar structure 322 of the third material is arranged to extend to the inner portion of the semiconductor substrate 300 from the first face 303. Because mobility of signal electric charges in the third material constituting the columnar structure 322 is higher than in the first material, photoelectrically converted electric charges moves through the columnar structure 322. The electric charges moving through the columnar structure 322 can reach the avalanche multiplication region earlier than the electric charges moving through the first material. As a result, it is possible to improve a response speed at which the electric charges are detected as signals.

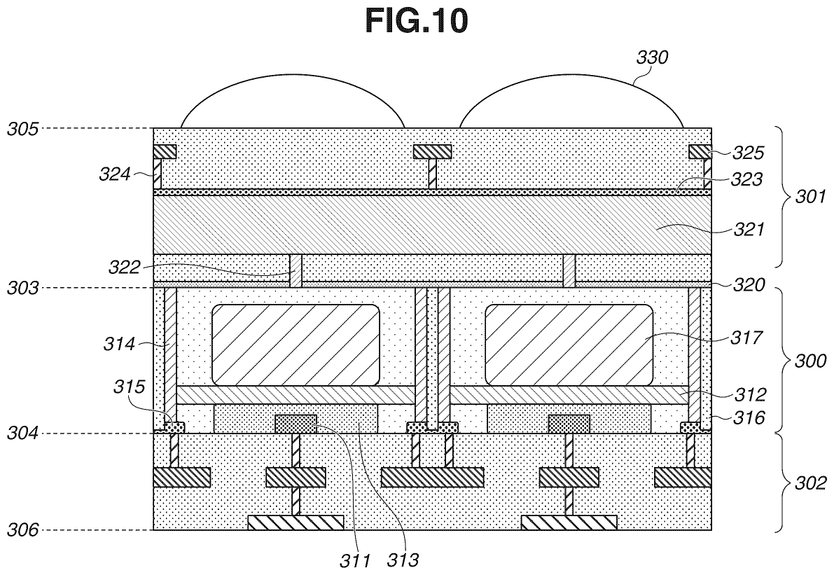

A photoelectric conversion device according to a fourth exemplary embodiment is described with reference to FIG. 10. Descriptions common to the photoelectric conversion devices according to the first to the third exemplary embodiments are omitted, and portions different from those of the photoelectric conversion device of the first exemplary embodiment are mainly described.

FIG. 10 is a diagram illustrating a cross-sectional view of two pixels 101 of the photoelectric conversion device according to the present exemplary embodiment. FIG. 10 is different from FIG. 8 in that the photoelectric conversion region 321 of the second material are arranged to be shared by a plurality of pixels 101 instead of being separately arranged for each of the pixels 101. For example, the photoelectric conversion region 321 may separately be arranged for a prescribed number of pixels 101 (e.g., four pixels 101), or one photoelectric conversion region 321 may be arranged for the entire pixel region 12. It is possible to improve the sensitivity to incident light by increasing the area of the photoelectric conversion region 321. Further, similar to the third exemplary embodiment, according to the photoelectric conversion device of the present exemplary embodiment, the semiconductor substrate 300 includes an electric charge collection region 317.

On the other hand, in one embodiment, the electric charges photoelectrically converted at the photoelectric conversion region 321 move to the semiconductor substrate 300 via the columnar structure 322. Similar to the second exemplary embodiment, as illustrated in FIG. 10, in order to uniformly supply potentials to the columnar structure 322 from the circumferential regions thereof, anode contacts 324 are arranged on the boundary portions between the pixels 101, close to the third face 305 of the photoelectric conversion layer 301. In a cross-sectional view, a boundary portion between pixels 101 corresponds to a position which the isolation trench 316 extends to. The anode voltage VL2 is applied to the photoelectric conversion region 321 from the metallic wiring 325 via the anode contacts 324. With this configuration, an electric field in the lateral direction is uniformly applied to the electric charges photoelectrically converted at the photoelectric conversion region 321, so that it is possible to prevent variation in charge-transfer time caused by deviation of the electric field. Further, voltage for inducing the electric charges to move to the avalanche multiplication region is sufficiently applied thereto. Therefore, similar to the second exemplary embodiment, it is possible to maintain a response speed at which the electric charges are detected as signals.

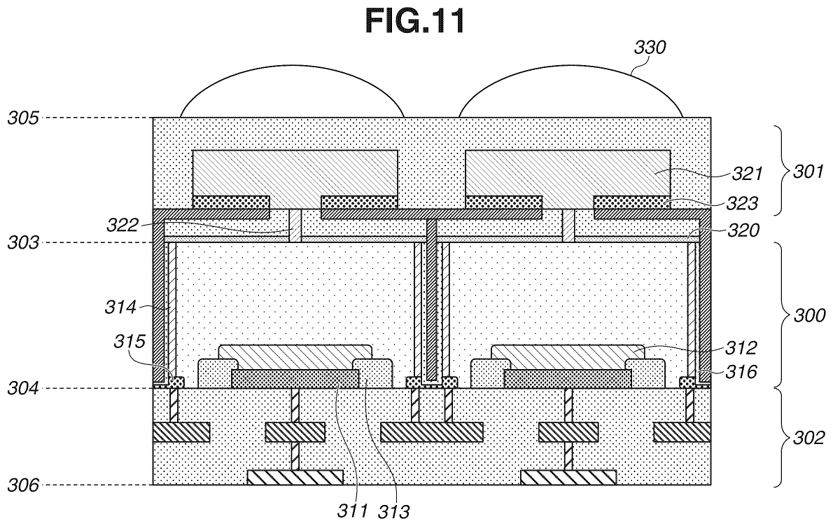

A photoelectric conversion device according to a fifth exemplary embodiment is described with reference to FIG. 11. Descriptions common to the photoelectric conversion devices according to the first to the fourth exemplary embodiments are omitted, and portions different from those of the photoelectric conversion device of the first exemplary embodiment are mainly described.

FIG. 11 is a diagram illustrating a cross-sectional view of two pixels 101 of the photoelectric conversion device according to the present exemplary embodiment. In the photoelectric conversion device illustrated in FIG. 11, a metallic material is embedded in the isolation trench 316 for isolating the pixels 101. The isolation trench 316 penetrates the semiconductor substrate 300, so that the metallic material embedded in the isolation trench 316 is joined to the photoelectric conversion region 321 with the sixth semiconductor region 323 therebetween, in a region close to the first face 303. The anode voltage VL is applied to the photoelectric conversion region 321.

By embedding the metallic material into the isolation trench 316 arranged on a boundary between the pixels 101, it is possible to prevent occurrence of cross talk caused by incident light or avalanche light generated and emitted when an electron and a hole are recombined in the avalanche multiplication region, being incident on the photoelectric conversion layer 301 of the adjacent pixel 101. Further, by increasing of the junction area between the metallic material embedded in the isolation trench 316 and the sixth semiconductor region 323, the metallic material functions as a reflection plate for reflecting incident light entering from the third face 305. As a result, light incident on the boundary portion between the pixels 101, regarded as a dead region of the photoelectric conversion layer 301, can also be reflected and incident on the photoelectric conversion region 321, to be thereby subjected to photoelectric conversion, so that it is possible to improve the photon detection efficiency (PDE) per pixel.

Further, in the photoelectric conversion device in FIG. 11, the areas of the first semiconductor region 311 and the second semiconductor region 312 for forming the avalanche multiplication region are wider than the areas thereof illustrated in FIG. 7. With this configuration, it is possible to improve a response speed and variation in time taken to detect, as signals, the electric charges that has photoelectrically converted and that has reached the avalanche multiplication region at the semiconductor substrate 300.

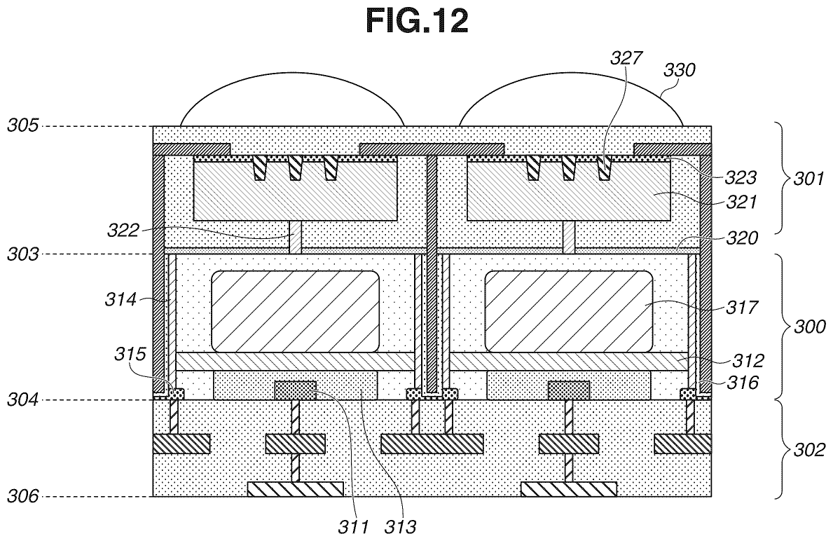

A photoelectric conversion device according to a sixth exemplary embodiment is described with reference to FIG. 12. Descriptions common to the photoelectric conversion devices according to the first to the fifth exemplary embodiments are omitted, and portions different from those of the photoelectric conversion device of the fourth exemplary embodiment are mainly described.

FIG. 12 is a diagram illustrating a cross-sectional view of two pixels 101 of the photoelectric conversion device according to the present exemplary embodiment. The metallic material embedded in the isolation trench 316 is joined to the photoelectric conversion region 321 with the sixth semiconductor region 323 therebetween, in a region close to the third face 305, and the anode potential VL is supplied to the photoelectric conversion region 321. When light is incident on the photoelectric conversion region 321 from the third face 305, the metallic material functions as a light shielding film to prevent light from being incident on a region other than the photoelectric conversion region 321, so that occurrence of optical cross talk is thereby prevented.

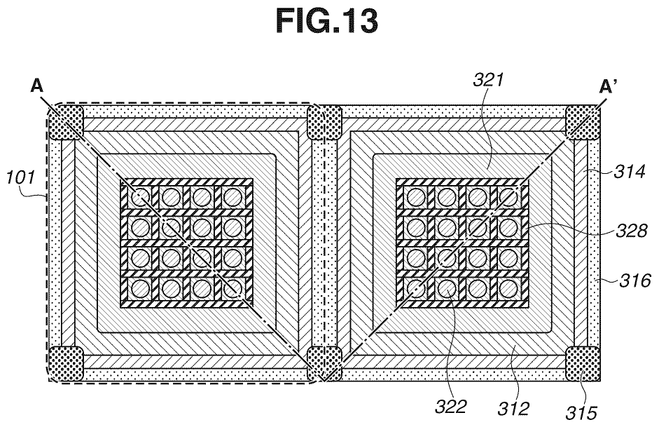

Further, in the photoelectric conversion device illustrated in FIG. 12, the semiconductor substrate 300 includes the electric charge collection region 317. A configuration of the avalanche diode is not limited to the above. For example, the avalanche diode may include a wide avalanche multiplication region as illustrated in FIG. 13.

The photoelectric conversion device further includes a first scattering diffraction structure 327 arranged in a region close to the third face 305 of the photoelectric conversion layer 301. For example, the first scattering diffraction structure 327 is a trench formed into a lattice shape. Light incident on the photoelectric conversion region 321 is diffracted and scattered by the first scattering diffraction structure 327. With this configuration, a propagation distance of light is increased, so that quantum efficiency can be improved. Further, because the photoelectric conversion layer 301 is surrounded by the metallic material extending from the isolation trench 316 for each pixel 101, light scattered by the first scattering diffraction structure 327 is reflected by the metallic material, and propagates in the photoelectric conversion region 321 for a plurality of times. Therefore, further improvement in quantum efficiency can be expected. The isolation trench 316 also prevents occurrence of cross talk in the adjacent pixels 101, caused by avalanche light generated and emitted when an electron and a hole are recombined in the avalanche multiplication region.

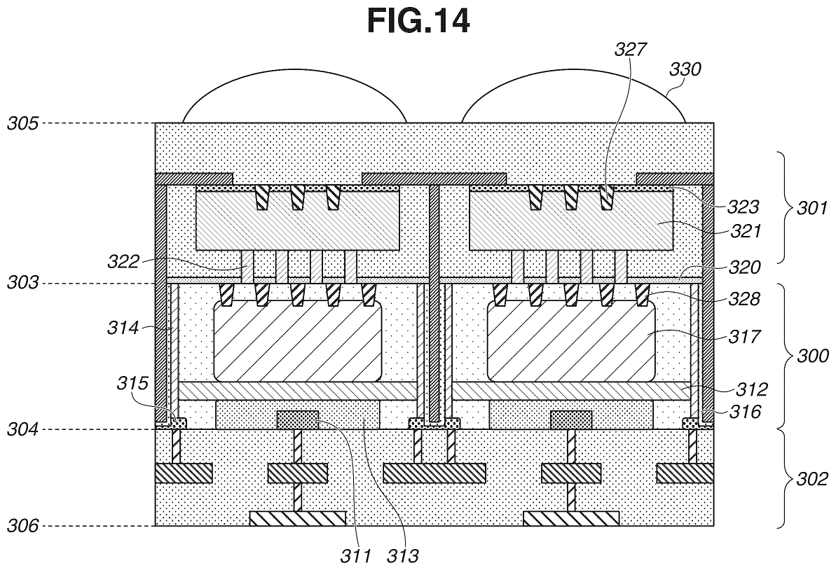

A photoelectric conversion device according to a seventh exemplary embodiment is described with reference to FIGS. 13 and 14. Descriptions common to the photoelectric conversion devices according to the first to the sixth exemplary embodiments are omitted, and portions different from those of the photoelectric conversion device of the sixth exemplary embodiment are mainly described.

FIG. 13 is a diagram illustrating a plan view of two pixels 101 of the photoelectric conversion device according to the present exemplary embodiment. FIG. 14 is a diagram illustrating a cross-sectional view taken along a line A-A′ in FIG. 13. The photoelectric conversion device according to the present exemplary embodiment includes a plurality of columnar structures 322 arranged on each of the pixels 101. The electric charges photoelectrically converted at the photoelectric conversion region 321 reach the avalanche multiplication region via the columnar structure 322 closest to a place where the photoelectric conversion has occurred, and are multiplied by the avalanche multiplication. Therefore, a response speed at which the photoelectric conversion device responds to incident light is improved, so that variation in time taken to detect the generated electric charges as signals can be improved.

Further, similar to the photoelectric conversion device illustrated in FIG. 12, the photoelectric conversion device according to the present exemplary embodiment includes a second scattering diffraction structure 328 arranged on the first face 303 of the semiconductor substrate 300, in addition to the first scattering diffraction structure 327 arranged in a region close to the third face 305 of the photoelectric conversion layer 301. For example, as illustrated in FIG. 13, the second scattering diffraction structure 328 has a lattice-shaped trench structure. The second scattering diffraction structure 328 does not overlap with each of the columnar structures 322 on a vertical line in a cross-sectional view and a planar view. Of the incident light entering from the third face 305, incident light which is neither diffracted by the first scattering diffraction structure 327 nor photoelectrically converted at the photoelectric conversion region 321, and which directly travels and reaches the semiconductor substrate 300, can be diffracted by the second scattering diffraction structure 328 and photoelectrically converted at the semiconductor substrate 300. Accordingly, the quantum efficiency can be improved by the second scattering diffraction structure 328.

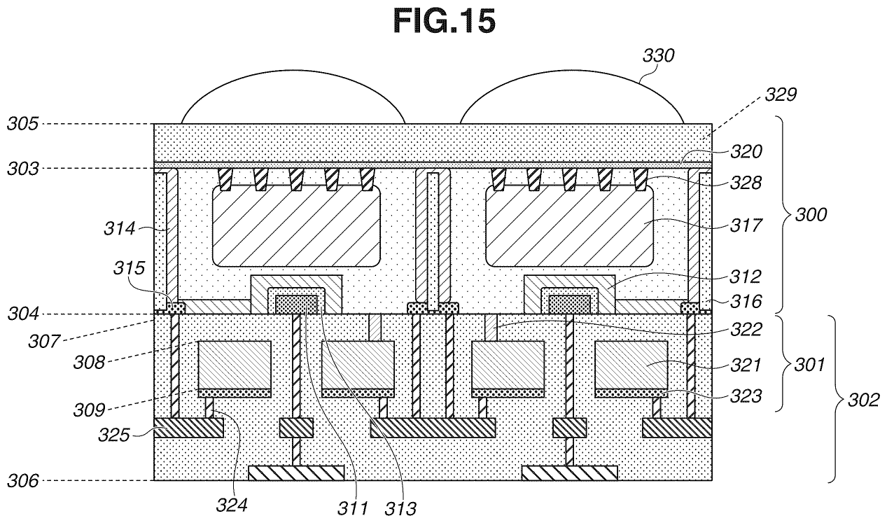

A photoelectric conversion device according to an eighth exemplary embodiment is described with reference to FIG. 15. Descriptions common to the photoelectric conversion devices according to the first to seventh exemplary embodiments are omitted, and portions different from those of the photoelectric conversion device of the first exemplary embodiment are mainly described.

FIG. 15 is a diagram illustrating a cross-sectional view of pixels 101 according to the present exemplary embodiment. FIG. 15 is different from FIG. 8 in that the photoelectric conversion layer 301 including the photoelectric conversion region 321 is formed on a face side opposite to the first face 303 side of the semiconductor substrate 300.

The photoelectric conversion device in FIG. 15 has a structure in which the semiconductor substrate 300 and a wiring layer 302 including the photoelectric conversion layer 301 are laminated in the cross-sectional view. The semiconductor substrate 300 is made of the first material, and has the first face 303 and the second face 304. A pinning film 320 and a planarization layer 329 are formed on the first face 303, and constitute the third face 305 as a light incident face. The second face 304 of the semiconductor substrate 300 is laminated to face a seventh face 307 of the wiring layer 302. The wiring layer 302 has a fourth face 306 opposite to the seventh face 307. The photoelectric conversion region 321, which is made of the second material, having an eighth face 308 and a ninth face 309 is arranged inside the wiring layer 302. The photoelectric conversion region 321 has a through-hole penetrating from the eighth face 308 to the ninth face 309 thereof, and a through electrode passing through the through-hole and an insulation film for covering the inner side of the through-hole are arranged on the through-hole. Further, the sixth semiconductor region 323 of the second material is arranged on the ninth face 309 of the photoelectric conversion region 321.

The first semiconductor region 311 of the first conductive type is arranged on the second face 304 of the semiconductor substrate 300, and the third semiconductor region 313 of the first conductive type and the second semiconductor region 312 of the second conductive type are arranged in a region closer to the first face 303 than the first semiconductor region 311. The impurity concentration of the first conductive type of the third semiconductor region 313 is lower than the impurity concentration of the first conductive type of the first semiconductor region 311. The semiconductor substrate 300 further includes the fourth semiconductor region 314 of the second conductive type and the fifth semiconductor region 315 of the second conductive type, and the second semiconductor region 312 is in contact with the fourth semiconductor region 314. Furthermore, the semiconductor substrate 300 includes the electric charge collection region 317 and the second scattering diffraction structure 328. Functions of the respective members are common to those of the members of the same names described in each of the exemplary embodiments.

A voltage VH (first voltage) is applied to the first semiconductor region 311 of the first conductive type. On the other hand, a voltage VL (second voltage) is supplied to the fifth semiconductor region 315 of the second conductive type, and the voltage VL is also applied to the second semiconductor region 312 of the second conductive type via the fourth semiconductor region 314 of the second conductive type. An avalanche multiplication region is formed in a region where the first semiconductor region 311 of the first conductive type and the second semiconductor region 312 of the second conductive type come close to each other.

According to the photoelectric conversion device of the present exemplary embodiment, light entering from the third face 305 is diffracted by the second scattering diffraction structure 328 arranged on the first face 303 of the semiconductor substrate 300, and part of the diffracted light is photoelectrically converted at the semiconductor substrate 300. Of the light incident thereon, components of the near-infrared waveband propagate into the wiring layer 302 and is photoelectrically converted at the photoelectric conversion region 321. The electric charges generated in the photoelectric conversion region 321 through the photoelectric conversion move to the semiconductor substrate 300 via the columnar structure 322, are collected into the electric charge collection region 317, are multiplied at the avalanche multiplication region, and are counted as signals.

According to the photoelectric conversion device of the present exemplary embodiment, it is possible to form the photoelectric conversion layer 301 before the wiring layer 302 is formed. By executing annealing at high temperature on the photoelectric conversion layer 301 before forming the wiring layer 302, it is possible to facilitate recovery of defects arising in the photoelectric conversion layer 301, and reduce noise.

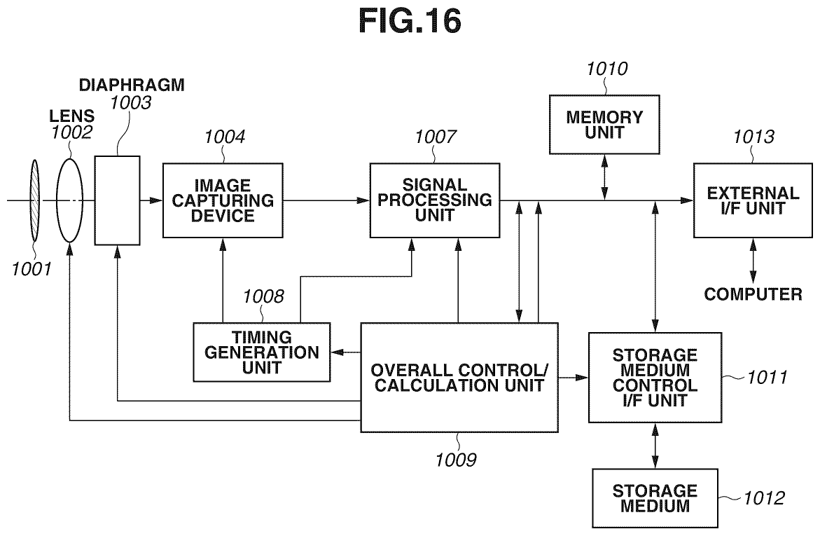

A photoelectric conversion system according to a present exemplary embodiment is described with reference to FIG. 16. FIG. 16 is a block diagram illustrating a schematic configuration of the photoelectric conversion system according to the present exemplary embodiment.

The photoelectric conversion devices described in the first to eighth exemplary embodiments can be applied to various types of photoelectric conversion system. A digital still camera, a digital camcorder, a monitoring camera, a copying machine, a facsimile machine, a mobile phone, an in-vehicle camera, and an observation satellite can be given as the examples of the photoelectric conversion systems to which the above-described photoelectric conversion device can be applied. Further, a camera module including an optical system such as a lens and an image capturing device is also included in the photoelectric conversion systems. FIG. 16 illustrates a block diagram of a digital camera as one example thereof.

The photoelectric conversion system illustrated in FIG. 16 includes an image capturing device 1004 as one example of the photoelectric conversion device and a lens 1002 which forms an optical object image on the image capturing device 1004. The photoelectric conversion system further includes a diaphragm 1003 capable of changing the amount of light passing through the lens 1002 and a barrier 1001 for protecting the lens 1002. The lens 1002 and the diaphragm 1003 serve as an optical system which condenses light to the image capturing device 1004. The image capturing device 1004 corresponds to a photoelectric conversion device according to any one of the above-described exemplary embodiments, and converts an optical image formed by the lens 1002 into an electric signal.

The photoelectric conversion system further includes a signal processing unit 1007 serving as an image generation unit for generating an image by processing a signal output from the image capturing device 1004. The signal processing unit 1007 executes processing for outputting image data by executing various types of correction and compression as necessary. The signal processing unit 1007 may be formed on a semiconductor substrate on which the image capturing device 1004 is mounted, or may be formed on a semiconductor substrate different from the semiconductor substrate the image capturing device 1004 is mounted.

The photoelectric conversion system further includes a memory unit 1010 for temporarily storing image data and an external interface (I/F) unit 1013 for communicating with an external computer. Furthermore, the photoelectric conversion system includes a storage medium 1012 such as a semiconductor memory for storing and reading the captured image data, and a storage medium control I/F unit 1011 through which the captured image data is stored in and read from the storage medium 1012. In addition, the storage medium 1012 may be built into the photoelectric conversion system, or may be attachable to and detachable from the photoelectric conversion system.

Furthermore, the photoelectric conversion system includes an overall control/calculation unit 1009 for executing various types of calculation and control of the entire digital still camera, and a timing generation unit 1008 for outputting various timing signals to the image capturing device 1004 and the signal processing unit 1007. Here, the timing signal may be input thereto from the outside. In this case, the photoelectric conversion system may include at least the image capturing device 1004 and the signal processing unit 1007 for processing the signal output from the image capturing device 1004.

The image capturing device 1004 outputs a captured image signal to the signal processing unit 1007. The signal processing unit 1007 outputs image data by executing prescribed signal processing on the captured image signal output from the image capturing device 1004. The signal processing unit 1007 generates an image by using the captured image signal.

As described above, according to the present exemplary embodiment, it is possible to realize a photoelectric conversion system to which the photoelectric conversion device (i.e., image capturing device) according to any one of the above-described exemplary embodiments is applied.

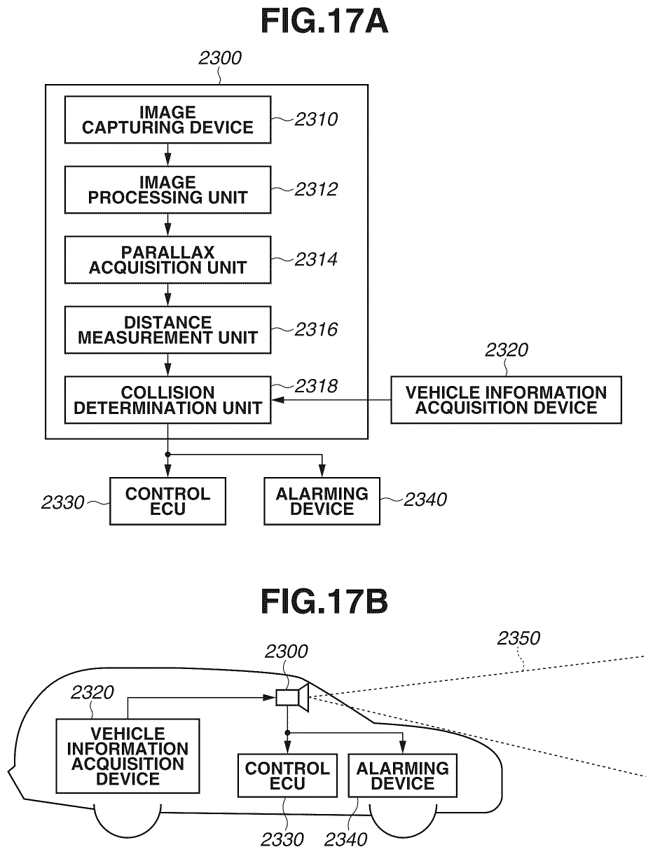

A photoelectric conversion system and a moving body according to a present exemplary embodiment are described with reference to FIGS. 17A and 17B. FIGS. 17A and 17B are diagrams illustrating configurations of a photoelectric conversion system 2300 and a moving body according to the present exemplary embodiment.

FIG. 17A is a diagram illustrating an example of the photoelectric conversion system 2300 applied to an in-vehicle camera. The photoelectric conversion system 2300 includes an image capturing device 2310. The image capturing device 2310 corresponds to the photoelectric conversion device according to any one of the above-described exemplary embodiments. The photoelectric conversion system 2300 includes an image processing unit 2312 for executing image processing on a plurality of pieces of image data acquired by the image capturing device 2310 and a parallax acquisition unit 2314 for executing calculation of a parallax (i.e., a phase difference between parallax images) from the plurality of pieces of image data acquired by the photoelectric conversion system 2300. The photoelectric conversion system 2300 further includes a distance measurement unit 2316 for calculating a distance to a target object based on the calculated parallax and a collision determination unit 2318 for determining whether there is a chance of collision based on the calculated distance. Here, the parallax acquisition unit 2314 and the distance measurement unit 2316 are examples of distance information acquisition units which acquire distance information indicating a distance to the target object. In other words, distance information refers to information about a parallax, a defocus amount, and a distance to a target object. The collision determination unit 2318 may determine a chance of collision by using any one of the pieces of above-described distance information. The distance information acquisition unit may be implemented by hardware exclusively designed, or may be implemented by a software module.

Further, the distance information acquisition unit may be implemented by a field programmable gate array (FPGA), an application specific integrated circuit (ASIC), or a combination of these elements. The photoelectric conversion system 2300 is connected to a vehicle information acquisition device 2320, and can acquire vehicle information such as a vehicle speed, a yaw rate, and a rudder angle. Further, a control ECU (ECU: electronic control unit) 2330 is connected to the photoelectric conversion system 2300. The control ECU 2330 serves as a control unit and outputs a control signal for causing the vehicle to generate braking power based on a determination result acquired by the collision determination unit 2318. An alarming device 2340 which issues a warning to a driver based on a determination result acquired by the collision determination unit 2318 is also connected to the photoelectric conversion system 2300. For example, in a case where the collision determination unit 2318 determines that a chance of collision is high, the control ECU 2330 executes vehicle control for avoiding a collision or reducing damages by applying a brake, releasing a gas pedal, or suppressing an engine output. The alarming device 2340 issues a warning to a driver by making alarm sound, displaying alarming information on a display screen of a car navigation system, or producing vibrations in a seat belt or a steering wheel.

In the present exemplary embodiment, peripheral views of the vehicle, e.g., a forward view and a backward view of the vehicle, are imaged by the photoelectric conversion system 2300. FIG. 17B is a diagram illustrating the photoelectric conversion system 2300 which images a forward view (image capturing range 2350) of the vehicle. The vehicle information acquisition device 2320 issues instructions to the photoelectric conversion system 2300 or the image capturing device 2310. Through the above-described configuration, range finding accuracy thereof can be further improved.

In the present exemplary embodiment, control which prevents a vehicle from colliding with another vehicle has been described as an example. However, the present disclosure is also applicable to control which makes a vehicle be automatically driven while following another vehicle or control which makes a vehicle be automatically driven without being drifted out of a traffic lane. Further, the photoelectric conversion system can be applied not only to vehicles such as automobiles but also to moving bodies (moving apparatuses) such as ships, airplanes, and industrial robots. Furthermore, the photoelectric conversion system can widely be applied to devices such as intelligent transportation systems (ITSs) which employ object recognition functions, in addition to the moving bodies.

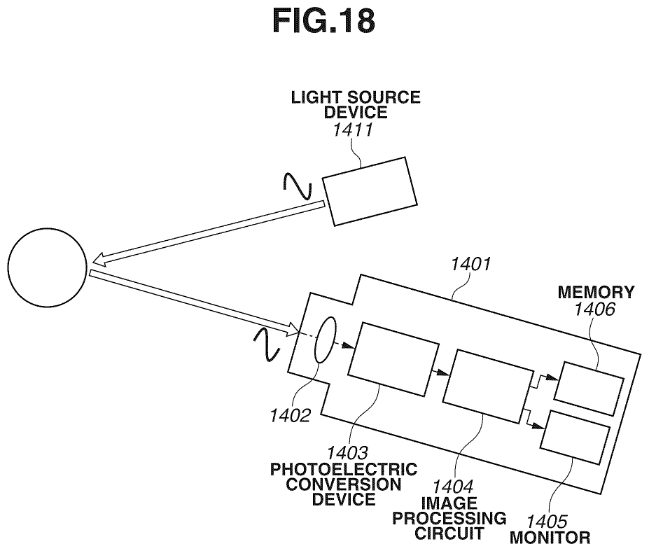

A photoelectric conversion system according to a present exemplary embodiment is described with reference to FIG. 18. FIG. 18 is a block diagram illustrating a configuration example of a distance image sensor 1401 regarded as a photoelectric conversion system according to the present exemplary embodiment.

As illustrated in FIG. 18, the distance image sensor 1401 includes an optical system 1402, a photoelectric conversion device 1403, an image processing circuit 1404, a monitor 1405, and a memory 1406. The distance image sensor 1401 can acquire a distance image based on a distance to an object by receiving light (modulated light or pulsed light) emitted from a light source device 1411 to the object and reflected on a surface of the object.

The optical system 1402 includes one or a plurality of lenses. The optical system 1402 guides the image light (incident light) from the object to the photoelectric conversion device 1403, and forms an image on a light receiving face (sensor portion) of the photoelectric conversion device 1403.

The photoelectric conversion device according to any one of the above-described exemplary embodiments is applied as the photoelectric conversion device 1403, and a distance signal indicating a distance acquired from a light receiving signal output from the photoelectric conversion device 1403 is supplied to the image processing circuit 1404.

The image processing circuit 1404 executes image processing to create a distance image based on the distance signal supplied from the photoelectric conversion device 1403. Then, the distance image (image data) acquired through the image processing is supplied to and displayed on the monitor 1405, or supplied to and stored (recorded) in the memory 1406.

By applying of the above-described photoelectric conversion device to the distance image sensor 1401 configured as the above, properties of pixels are improved, so that a distance image with higher accuracy can be thereby acquired.

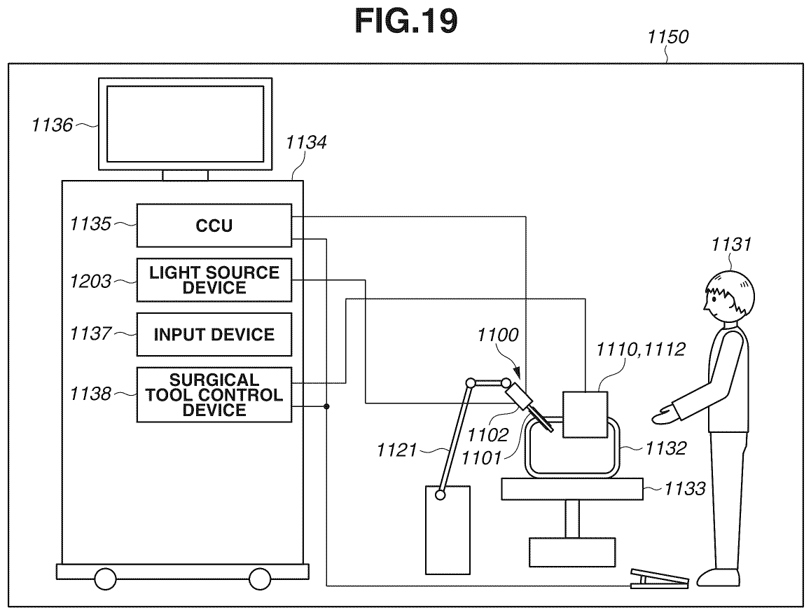

A photoelectric conversion system according to a present exemplary embodiment is described with reference to FIG. 19. FIG. 19 is a diagram illustrating an example of a schematic configuration of an endoscopic operation system 1150 regarded as a photoelectric conversion system according to the present exemplary embodiment.

In FIG. 19, an operator (doctor) 1131 performs a surgical operation on a patient 1132 lying on a patient bed 1133 by using the endoscopic operation system 1150. As illustrated in FIG. 19, the endoscopic operation system 1150 includes an endoscope 1100, a surgical tool 1110, and a cart 1134 on which various devices used for the endoscopic operation are mounted.

The endoscope 1100 includes a lens tube 1101, whose leading end region of a prescribed length is inserted to a coelom of the patient 1132, and a camera head 1102 connected to a base end section of the lens tube 1101. In the example illustrated in FIG. 19, the endoscope 1100 is illustrated as a so-called rigid endoscope having a rigid lens tube 1101. However, the endoscope 1100 can be a so-called flexible endoscope having a flexible lens tube.

A leading end of the lens tube 1101 includes an opening portion on which an objective lens is mounted. A light source device 1203 is connected to the endoscope 1100, so that light generated by the light source device 1203 is guided to the leading end of the lens tube 1101 by a light guide arranged to extend to the inner portion of the lens tube 1101, so as to be emitted to an observation target inside the coelom of the patient 1132 via the objective lens. In addition, the endoscope 1100 can be a forward viewing endoscope, an oblique viewing endoscope, or a side viewing endoscope.

An optical system and a photoelectric conversion device are arranged on the inner portion of the camera head 1102, and reflection light (observation light) reflected from the observation target is condensed to the photoelectric conversion device through the optical system. The photoelectric conversion device executes photoelectric conversion of the observation light and generates an electric signal corresponding to the observation light, i.e., an image signal corresponding to an observation image. The photoelectric conversion device according to any one of the above-described exemplary embodiments can be used as the photoelectric conversion device. The image signal is transmitted to a camera control unit (CCU) 1135 in a form of RAW data.

The CCU 1135 includes a central processing unit (CPU) and a graphics processing unit (GPU), and comprehensively controls the operations of the endoscope 1100 and a display device 1136. Further, the CCU 1135 receives an image signal from the camera head 1102, and executes various types of image processing such as development processing (de-mosaic processing) on the image signal to display an image based on the image signal.

The display device 1136 is controlled by the CCU 1135 to display an image based on the image signal on which the image processing is executed by the CCU 1135.

The light source device 1203 includes a light source such as a light emitting diode (LED), and supplies irradiation light to the endoscope 1100 when an operative field image is to be captured.

An input device 1137 serves as an input interface of the endoscopic operation system 1150. The user can input various types of information and instructions to the endoscopic operation system 1150 via the input device 1137.

A surgical tool control device 1138 executes driving control of an energy surgical tool 1112 used to cauterize living tissues, incise living tissues, or seal a blood vessel.

The light source device 1203, which supplies irradiation light to the endoscope 1100 when an operative field image is to be captured, can be an LED, a laser light source, or a white light source configured of a combination of these elements. In a case where the white light source is configured of a combination of RGB laser light sources, output intensities and output timings of the laser light sources of respective colors (wavelengths) can be controlled with high accuracy. Therefore, the light source device 1203 can execute adjustment of a white balance of the captured image. In this case, the observation target is irradiated with laser light beams respectively emitted from the RGB laser light sources in a time division manner, and image sensors mounted on the camera head 1102 are controlled and driven in synchronization with the irradiation timing. In this way, images corresponding to respective RGB laser beams can be captured in a time division manner. Through the above-described method, color images can be acquired even if color filters are not arranged on the image sensors.

Further, the light source device 1203 may be controlled and driven to change the intensity of output light at every prescribed time. The endoscopic operation system 1150 acquires images in a time division manner by executing driving control of the image sensors mounted on the camera head 1102 in synchronization with the timing of changing the light intensity, and can generate so-called wide dynamic range image data without including overexposed or underexposed data by combining the acquired images.

The light source device 1203 may supply light of a prescribed wavelength band suitable to conduct special light observation. For example, the special light observation is executed by making use of wavelength dependence characteristics of light absorption of the living tissues. Specifically, specific tissues such as blood vessels in a mucous membrane surface are captured with high contrast by irradiating the tissues with light of a wavelength band narrower than a wavelength band of irradiation light (i.e., white light) used for normal observation.

Alternatively, fluorescence observation for acquiring an image of generated fluorescence may be executed as the special light observation by irradiating the living tissues with excitation light. In the fluorescence observation, fluorescence generated from the living tissues can be observed by irradiating the living tissues with excitation light. Further, a fluorescent image can be acquired by locally injecting test reagent such as indocyanine green (ICG) into the living tissues and irradiating the living tissues with excitation light corresponding to the fluorescence wavelength of that test reagent. The light source device 1203 can supply narrow-band light and/or excitation light corresponding to the special light observation described above.

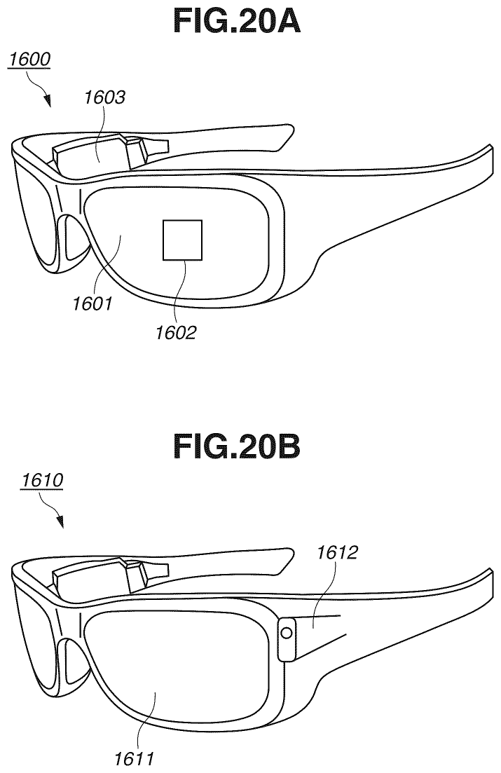

A photoelectric conversion system according to a present exemplary embodiment is described with reference to FIGS. 20A and 20B. FIG. 20A is a diagram illustrating a pair of eyeglasses 1600 (a pair of smart-glasses) regarded as the photoelectric conversion system according to the present exemplary embodiment. The pair of eyeglasses 1600 includes a photoelectric conversion device 1602. The photoelectric conversion device 1602 is the photoelectric conversion device according to any one of the above-described exemplary embodiments. Further, a display device including a light emitting device such as an organic light emitting diode (OLED) or an LED may be mounted on a back face of each of lenses 1601. One or more photoelectric conversion devices 1602 may be mounted thereon. Further, a plurality of types of photoelectric conversion devices may be used in combination. A mounting position of the photoelectric conversion device 1602 is not limited to the position indicated in FIG. 20A.

The pair of eyeglasses 1600 further includes a control device 1603. The control device 1603 functions as a power source for supplying power to the photoelectric conversion device 1602 and the above-described display device. The control device 1603 further controls the operations of the photoelectric conversion device 1602 and the display device. An optical system which condenses light to the photoelectric conversion device 1602 is formed on the lens 1601.

FIG. 20B is a diagram illustrating a pair of eyeglasses 1610 (a pair of smart-glasses) according to one application example. The pair of eyeglasses 1610 includes a control device 1612, and a photoelectric conversion device corresponding to the photoelectric conversion device 1602 and a display device are mounted on the control device 1612. An optical system for projecting light emitted from the photoelectric conversion device and the display device included in the control device 1612 is formed on each of lenses 1611, so that images are projected thereon. The control device 1612 functions as a power source for supplying power to the photoelectric conversion device and the display device, and also controls the operations of the photoelectric conversion device and the display device. The control device 1612 may include a line-of-sight detection unit for detecting a line-of-sight of the user. Infrared light may be used to detect the line-of-sight. An infrared light emitting unit emits infrared light to the eyeballs of the user who is gazing at a displayed image. An image capturing unit having a light receiving element detects the emitted infrared light reflected on the eyeballs, so that captured images of the eyeballs can be acquired. Degradation of image quality can be suppressed by a reduction unit which reduces light emitted from the infrared light emitting unit to a display unit in a planar view.

A line-of-sight of the user gazing at the displayed image is detected from the captured images of the eyeballs acquired through the image capturing using infrared light. A known method can optionally be employed for the line-of-sight detection using the captured images of the eyeballs. For example, it is possible to employ a line-of-sight detection method based on a Purkinje image acquired from irradiation light reflected on the cornea.

More specifically, line-of-sight detection processing is executed based on a pupil-corneal reflection method. By employing the pupil-corneal reflection method, a line-of-sight vector which expresses the orientation (rotation angle) of the eyeball is calculated based on the pupil image and the Purkinje image included in the captured image of the eyeball, and the user's line-of-sight is detected from the calculated line-of-sight vector.

The display device according to the present exemplary embodiment may include a photoelectric conversion device having a light emitting element, and may control an image displayed on the display device based on the user's line-of-sight information received from the photoelectric conversion device.

Specifically, based on the line-of-sight information, a first field-of-view region and a second field-of-view region of the display device are determined. The first field-of-view region is a region the user is gazing at, and the second field-of-view region is a region different from the first field-of-view region. The first and second field-of-view regions may be determined by the control device of the display device, or the display device may receive the first and second field-of-view regions determined by an external control device. In the display region of the display device, a display resolution of the first field-of-view region may be controlled to be higher than the display resolution of the second field-of-view region. In other words, the resolution of the second field-of-view region may be lower than the resolution of the first field-of-view region.

Further, the display region has a first display region and a second display region different from the first display region, and a region of higher priority may be determined from the first and second display regions based on the line-of-sight information. The first and second display regions may be determined by the control device of the display device, or the display device may receive the first and second display regions determined by an external control device. A resolution of the region of higher priority may be controlled to be higher than a resolution of the region different from the region of higher priority. In other words, a resolution of the region of relatively low priority may be controlled to be lower.

In addition, an artificial intelligence (AI) program may be used to determine the first field-of-view region and the region of higher priority. The AI program can be a model designed to estimate an angle of the line-of-sight and a distance to the object to which the line-of-sight is directed from the image of the eyeball, by using the image of the eyeball and the actual line-of-sight direction of the eyeball captured in that image as teaching data. The AI program may be included in the display device, the photoelectric conversion device, or the external device. In a case where the AI program is included in the external device, the information is transmitted to the display device through communication.

In a case where display control is executed based on visual recognition detection, the present exemplary embodiment can favorably be applied to a pair of smart-glasses which further includes a photoelectric conversion device for capturing an outside view. The pair of smart-glasses can display information about the captured outside view in real time.

### Variation Exemplary Embodiment

The present disclosure is not limited to the above-described exemplary embodiments, and various changes and modifications are possible.

For example, an exemplary embodiment in which part of the configuration according to any one of the above-described exemplary embodiments is added to another exemplary embodiment or replaced with part of the configuration according to another exemplary embodiment is also included in the exemplary embodiments of the present disclosure.

Further, the photoelectric conversion systems described in the ninth to thirteenth exemplary embodiments are merely the examples of the photoelectric conversion system to which the photoelectric conversion device can be applied, and the photoelectric conversion system to which the photoelectric conversion device according to the present disclosure is applicable is not limited to those illustrated in FIG. 16 to FIGS. 20A and 20B. The same can also be said for the ToF system described in the eleventh exemplary embodiment, the endoscopic operation system described in the twelfth exemplary embodiment, and the pair of smart-glasses described in the thirteenth exemplary embodiment.

In addition, the above-described exemplary embodiments are merely the examples embodying the present disclosure, and shall not be construed as limiting the technical range of the present disclosure. In other words, the present disclosure can be realized in diverse ways without departing from the technical spirit or main features of the present disclosure.

According to the present disclosure, it is possible to suppress noise arising in the junction interface between different materials.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2023-083367, filed May 19, 2023, which is hereby incorporated by reference herein in its entirety.

What is claimed is:

1. A conversion device comprising:
a substrate made of a first material, which includes a photodiode;
a conversion layer made of a second material whose band gap is smaller than a band gap of the first material; and
a region made of a third material at least including an element of the first material or the second material, the region being in contact with the substrate and the conversion layer,
wherein the region is surrounded by an insulating material, and an area of the region is smaller than an area of the conversion layer in a top plan view.

2. The conversion device according to claim 1, wherein the third material and the first material are the same material.

3. The conversion device according to claim 1, wherein the third material and the second material are the same material.

4. The conversion device according to claim 1, wherein the first material is silicon, and the second material contains germanium.

5. The conversion device according to claim 4, wherein the second material is germanium.

6. The conversion device according to claim 1, wherein the first material is silicon, and the second material is indium gallium arsenide.

7. The conversion device according to claim 1, wherein the region overlaps with a multiplication region of the photodiode in a top plan view.

8. The conversion device according to claim 1,
wherein the photodiode includes a first region of a first conductive type and a second region of a second conductive type,
wherein the conversion layer includes a third region, and
wherein voltage is applied to each of the first region, the second region, and the third region.

9. The conversion device according to claim 8, wherein an electrode is arranged to overlap with the third region in a top plan view.

10. The conversion device according to claim 1, wherein the region extends into the substrate from a face of the substrate which faces the conversion layer.

11. The conversion device according to claim 1, further comprising:
a first photodiode and a second photodiode,
wherein an isolation portion is arranged in a region between the first photodiode and the second photodiode, and
wherein a contact which supplies voltage to the first photodiode is arranged immediately above the isolation portion.

12. The conversion device according to claim 1,
wherein a first pixel including a first photodiode and a first conversion layer and a second pixel including a second photodiode and a second conversion layer are arranged next to each other, and
wherein a shielding portion formed in a region between the first pixel and a second pixel is in contact with a lower portion of the first conversion layer and supplies potential.

13. The conversion device according to claim 1,
wherein a first pixel including a first photodiode and a first conversion layer and a second pixel including a second photodiode and a second conversion layer are arranged next to each other, and
wherein a shielding portion formed in a region between the first pixel and a second pixel is in contact with an upper portion of the first conversion layer and supplies potential.

14. The conversion device according to claim 1, wherein a thickness of the substrate is smaller than a thickness of the conversion layer in a cross-sectional view.

15. The conversion device according to claim 1, wherein a pinning film is formed at a place excluding a junction portion of the substrate and the region.

16. The conversion device according to claim 1, further comprising a scattering diffraction structure on a light incident face of the substrate.

17. The conversion device according to claim 1, further comprising a scattering diffraction structure in the region.

18. The conversion device according to claim 1, wherein the conversion device includes the plurality of regions with respect to the one conversion layer.

19. The conversion device according to claim 1,
wherein a wiring layer is arranged to be laminated on the substrate, and
wherein the conversion layer is formed on a side of one face of the substrate on which the wiring layer is laminated.

20. The conversion device according to claim 1,
wherein a wiring layer is arranged to be laminated on the substrate, and
wherein the conversion layer is formed on a side of one face of the substrate opposite to another face of the substrate on which the wiring layer is laminated.

21. A conversion system comprising:
the conversion device according to claim 1; and
a processing unit configured to generate an image by using a signal output from the conversion device.

22. A moving body including the conversion device according to claim 1, the moving body comprising a control unit configured to control movement of the moving body by using a signal output from the conversion device.
